(19) United States
(12) Patent Application Publication
(10) Pub. No.: US 2017/0005249 A1
(43) Pub. Date: Jan. 5, 2017

(54) INSULATOR AND CONNECTOR FOR THERMOELECTRIC DEVICES IN A THERMOELECTRIC ASSEMBLY

(71) Applicant: GENTHERM GMBH, Odelzhausen (DE)

(72) Inventor: Shaun Peter McBride, Augsburg (DE)

(21) Appl. No.: 15/125,770

(22) PCT Filed: Mar. 12, 2015
(86) PCT No.: PCT/IB2015/000322

§ 371 Date: Sep. 13, 2016

(30) Foreign Application Priority Data
Mar. 14, 2014 (DE) 10 2014 003 492.5

(51) Int. Cl. H01L 35/10; H01L 35/34; H01M 10/6572; H01L 35/32

(52) U.S. Cl. CPC H01L 35/10; H01L 35/32; H01L 35/34; H01M 10/6572

(57) ABSTRACT

A thermoelectric assembly comprises an insulator, a current carrier, and thermoelectric assemblies. The insulator has openings extending through the insulator from a first side to a second side, and receptacles located between the first and second sides. The current carrier is releasably secured to the insulator, and has ends. The thermoelectric assemblies are within the openings, and have terminals connected to the ends. A method of assembling a thermoelectric assembly comprises providing an insulating part, current carriers, and thermoelectric devices. The insulating part includes a) openings extending through the insulating part from a first side to a second side and b) receptacles located between the first and second sides. The thermoelectric devices include terminals. The method further includes engaging the current carriers within the receptacles, receiving the thermoelectric devices within the openings, and electrically connecting the thermoelectric devices via the current carriers.

### BACKGROUND

Field

This disclosure relates generally to thermoelectric cooling and heating devices, and more particularly to thermoelectric assemblies.

Description of the Related Art

Power electronics and other electrical devices, such as batteries, can be sensitive to overheating, cold temperatures, extreme temperatures, and operating temperature limits. The performance of such devices may be diminished, sometimes severely, when the devices are operated outside of recommended temperature ranges. In semiconductor devices, integrated circuit dies can overheat and malfunction. In batteries, including, for example, batteries used for automotive applications in electrified vehicles, battery cells and their components can degrade when overheated or overcooled. Such degradation can manifest itself in reduced battery storage capacity and/or reduced ability for the battery to be recharged over multiple duty cycles.

### SUMMARY

It can be advantageous to manage the thermal conditions of power electronics and other electrical devices. Thermal management can reduce incidences of overheating, overcooling, and electrical device degradation. Certain embodiments described herein provide thermal management of devices that carry significant electric power and/or require high current and efficiency (e.g., power amplifiers, transistors, transformers, power inverters, insulated-gate bipolar transistors (IGBTs), electric motors, high power lasers and light-emitting diodes, batteries, and others). A wide range of solutions can be used to thermally manage such devices, including convective air and liquid cooling, conductive cooling, spray cooling with liquid jets, thermoelectric cooling of boards and chip cases, and other solutions.

In various embodiments disclosed in more detail below, the present teachings provide a thermoelectric assembly and a method of assembling the thermoelectric assembly. In one example, a thermoelectric assembly includes an insulator, a current carrier, and thermoelectric assemblies. The insulator has openings and receptacles. The openings extend through the insulator from a first side to a second side. The receptacles are located between the first and second sides. The current carrier is releasably secured to the insulator, and has ends. The thermoelectric assemblies are received within the openings, and have terminals connected to the ends.

In one example, a method of assembling a thermoelectric assembly includes the steps of providing an insulating part including a) openings extending through the insulating part from a first side to a second side and b) receptacles located between the first and second sides; engaging current carriers within the receptacles; receiving thermoelectric devices within the openings, the thermoelectric devices having terminals; and electrically connecting the thermoelectric devices via the current carriers.

### BRIEF DESCRIPTION OF THE DRAWINGS

Various embodiments are depicted in the accompanying drawings for illustrative purposes, and should in no way be interpreted as limiting the scope of the present disclosure. In addition, various features of different disclosed embodiments can be combined with one another to form additional embodiments, which are part of this disclosure. Any feature or structure can be removed, altered, or omitted. Throughout the drawings, reference numbers may be reused to indicate correspondence between reference elements.

FIG. 1 is a perspective view illustrating a battery and an exemplary thermal management system for the battery according to the present disclosure.

FIG. 2 is an exploded perspective view illustrating the thermal management system of FIG. 1 in further partial detail.

FIG. 3 is a block diagram schematically illustrating an exemplary thermoelectric assembly according to the present disclosure.

FIG. 4 is a sectional view along line A-A of FIG. 3 schematically illustrating the thermoelectric assembly in further detail.

FIG. 5 is a sectional view along line B-B of FIG. 3 schematically illustrating the thermoelectric assembly in further detail.

FIG. 6 is a sectional view along line B-B of FIG. 3 schematically illustrating an exemplary connection and current carriers of the thermoelectric assembly in further detail.

FIG. 7 is a sectional view illustrating an alternate connection and alternate current carriers for the thermoelectric assembly according to the present disclosure.

### DETAILED DESCRIPTION

The present teachings are illustrated by embodiments and examples disclosed herein, however the present teachings apply beyond the examples and embodiments to other alternative embodiments and/or uses, and to modifications and equivalents thereof. Thus, the scope of the claims appended hereto is not limited by any of the particular embodiments described below. For example, in any method or process disclosed herein, the acts or operations of the method or process may be performed in any suitable sequence and are not necessarily limited to any particular disclosed sequence. Various operations may be described as multiple discrete operations in turn, in a manner that may be helpful in understanding certain embodiments; however, the order of description should not be construed to imply that these operations are order dependent. Additionally, the structures, systems, and/or devices described herein may be embodied as integrated components or as separate components. For purposes of comparing various embodiments, certain aspects and advantages of these embodiments are described. Not necessarily all such aspects or advantages are achieved by any particular embodiment. Thus, for example, various embodiments may be carried out in a manner that achieves or optimizes one advantage or group of advantages as taught herein without necessarily achieving other aspects or advantages as may also be taught or suggested herein.

It can be advantageous to manage the thermal conditions of electronics and electrical devices. Such thermal management can reduce incidences of overheating, overcooling, and electrical device degradation. Certain embodiments described herein provide thermal management of devices that carry significant electric power and/or require high current and efficiency (e.g., power amplifiers, transistors, transformers, power inverters, insulated-gate bipolar transistors (IGBTs), electric motors, high power lasers and light-emitting diodes, batteries, and others). A wide range of solutions can be used to thermally manage such devices, including convective air and liquid cooling, conductive cooling, spray cooling with liquid jets, thermoelectric cooling of boards and chip cases, and other solutions. At least some embodiments disclosed herein provide at least one of the following advantages compared to existing techniques for heating or cooling electrical devices: higher power efficiency, lower or eliminated maintenance costs, greater reliability, longer service life, fewer components, fewer or eliminated moving parts, heating and cooling modes of operation, other advantages, or a combination of advantages.

In electrical devices, typically electrically active portions and/or temperature sensitive regions of the device are connected to the outside world, such as, for example, external circuits or devices, via electrical conductors. For example, electrodes of a battery cell can be designed to carry high electric power without significant losses (e.g., heat losses that are proportional to the square of the current, per Joule's Law). The wire gauge of the electrical conductors used for such electrodes is commensurate with the high current that typically flows in such devices. The larger the size of the battery is, the bigger are the electrode posts for connection with the outside circuits.

The high electrical conductance of electrodes and many other types of electrical conductors also means that such conductors typically have high thermal conductivity. The high thermal conductivity can be used to solve various thermal management problems, where one can deliver desired thermal power (e.g., cooling, heating, etc.) directly to the sensitive elements of the device by heating and/or cooling the electrodes, bypassing thermally-insensitive elements of the device. Similar to using thermally conditioned blood during blood transfusions for delivering heat deep to the core of human bodies, heat pumping through the electrodes can be used to efficiently deliver desired thermal conditions deep inside an electrical device. As an example, it has been determined that electrode cooling of advanced automotive batteries is one of the most advantageous techniques for battery thermal management. For example, the electrodes can be cooled using solid, liquid, or air cooling techniques. In a sense, electrodes act as cold fingers in such a thermal management arrangement.

Embodiments disclosed herein include systems and methods capable of thermally managing an electrical device by applying direct or indirect thermoelectric (TE) cooling and/or heating to current carrying electrical conductors (e.g., electrodes) of power components, electronics, and other electrical devices. Such devices can often benefit from thermal management. Some embodiments will be described with reference to particular electrical devices, such as, for example, batteries. However, at least some embodiments disclosed herein are capable of providing thermal management to other electrical devices, such as, for example, insulated-gate bipolar transistors (IGBTs), other electrical devices, or a combination of devices. At least some such devices can have high current carrying capacity and can suffer from operation outside of a preferred temperature range. The operation of some embodiments is described with reference to a cooling mode of operation. However, some or all of the embodiments disclosed herein can have a heating mode of operation, as well. In some situations a heating mode of operation can be employed to maintain the temperature of an electrical device above a threshold temperature, under which the electrical device may degrade or exhibit impaired operation. TE devices are uniquely suited to provide both heating and cooling functions with minimum complications for system architecture.

There are a variety of ways in which TE devices can be used for electrical conductor cooling and/or heating tasks. As described herein, TE devices can include one or more TE elements, TE assemblies and/or TE modules. In some embodiments, a TE system can include a TE device, which comprises a first side and a second side opposite the first side. In some embodiments, the first side and second side can be a main surface and waste surface or heating surface and cooling surface. A TE device can be operably coupled with a power source. The power source can be configured to apply a voltage to the TE device. When voltage is applied in one direction, one side (e.g., the first side) creates heat while the other side (e.g., the second side) absorbs heat. Switching polarity of the circuit creates the opposite effect. In a typical arrangement, a TE device comprises a closed circuit that includes dissimilar materials. As a DC voltage is applied to the closed circuit, a temperature difference is produced at the junction of the dissimilar materials. Depending on the direction of the electric current, heat is either emitted or absorbed at a particular junction. In some embodiments, the TE device includes several solid state P- and N-type semi-conductor elements connected in series. In certain embodiments, the junctions are sandwiched between two electrical isolation members (e.g., ceramic plates), which can form the cold side and the hot side of the TE device. The cold side can be thermally coupled to an object (e.g., electrical conductor, electrical device under thermal management, etc.) to be cooled and the hot side can be thermally coupled to a heat sink which dissipates heat to the environment. In some embodiments, the hot side can be coupled to an object (e.g., electrical conductor, electrical device under thermal management, etc.) to be heated. Certain non-limiting embodiments are described below.

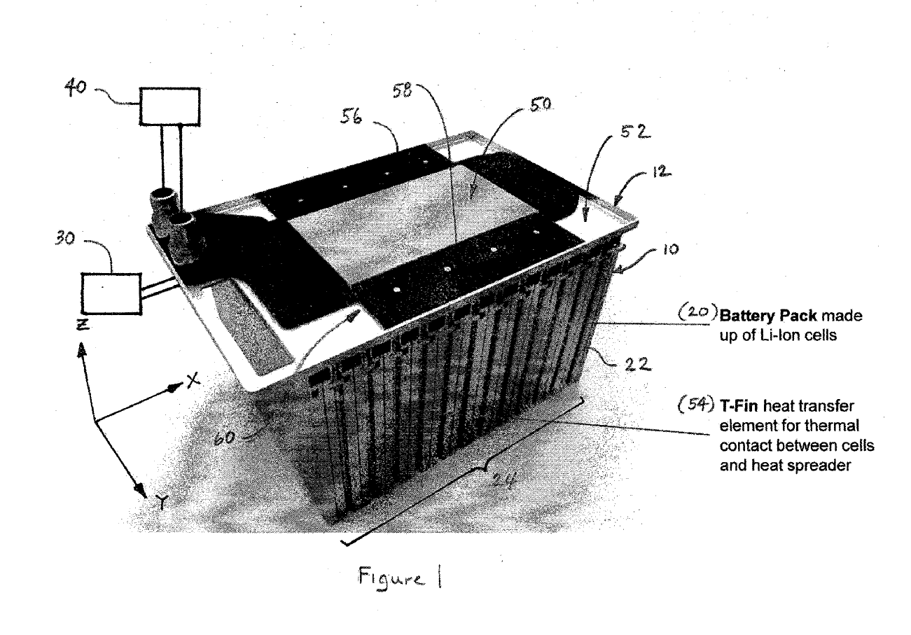

FIG. 1 is a perspective view illustrating a battery 10 and an exemplary thermal management system (TMS) 12 for the battery 10 according to the present disclosure. The battery 10 is of the Lithium-Ion (Li-Ion) type, however the present teachings are not limited to Li-Ion batteries. The battery 10 includes a battery pack 20 including a plurality of N cells 22 arranged in a stack 24 along a longitudinal axis X, N being an integer greater than 1. The TMS 12 is thermally coupled to a side of the battery 10 and is operable to cool the battery 10. The TMS 12 is operably coupled to a power supply and control system schematically represented by reference numeral 30. The TMS 12 is operably coupled to a coolant system schematically represented by reference numeral 40.

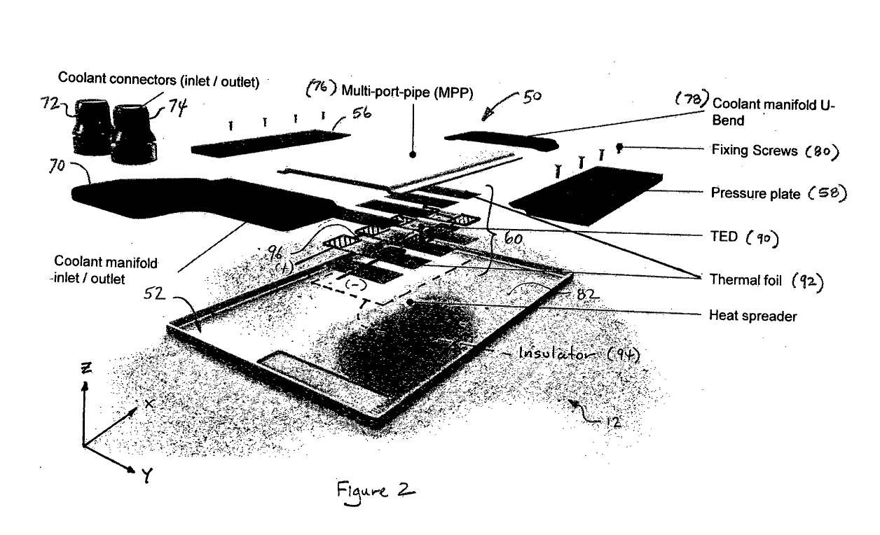

FIG. 2 is an exploded perspective view illustrating the TMS 12 in further detail. The TMS 12 includes a first heat exchanger (HEX) 50, a second HEX 52, heat transfer elements 54, pressure plates 56, 58, and a thermoelectric (TE) assembly 60. The HEX 50 is thermally coupled to a waste side of the TE assembly 60. The HEX 50 receives heat from the TE assembly 60 and transfers the heat to the surroundings. The HEX 50 can be a multi-port-pipe heat exchanger as illustrated and now further described, however the present teachings are not limited to multi-port-pipe heat exchangers.

The HEX 50 includes a first coolant manifold 70, coolant inlet and outlet connectors 72 and 74, a multi-port-pipe (MPP) 76, and a second coolant manifold 78. Together, the coolant manifold 70 and coolant inlet and outlet connectors 72 and 74 form an inlet and outlet. The inlet and outlet are illustrated by the openings in the coolant manifold 70 and the coolant inlet and outlet connectors 72 and 74 in FIGS. 1 and 2. Coolant circulating between the HEX 50 and the coolant system 40 enters the HEX 50 through the inlet and exits the HEX 50 from the outlet. The coolant inlet and outlet connectors 72 and 74 fluidly and mechanically couple the HEX 50 to the coolant system 40.

The HEX 52 is thermally coupled to a main side of the TE assembly 60 on a first side or major face and the heat transfer elements 54 on a second side or major face opposite the first side. The HEX 52 receives heat generated by the battery 10 from the heat transfer elements 54 and transfers the heat to the TE assemblies 60. The HEX 52 can be a heat spreader having a generally planar shape as illustrated, however the present teachings are not limited to heat spreaders.

The heat transfer elements 54 are each disposed between and thermally coupled to a corresponding pair of adjacent cells 22 in a first direction along axis X. The heat transfer elements 54 are each disposed between the corresponding adjacent cells 22 and the HEX 52 in a second direction along axis Z. The heat transfer elements 54 receive heat from the cells 22 in the first direction and transfer the heat to the HEX 52 in the second direction. The heat transfer elements 54 can be thermally conductive fins having a generally “T” shape as illustrated, although the present teachings are not limited to heat transfer elements of a particular shape.

The pressure plates 56, 58 cooperate with the HEX 50 and the HEX 52 and thereby mechanically couple the HEX 50, the HEX 52, and the TE assembly 60. In various embodiments according to the present teachings, the pressure plates 56, 58 compress the TE assembly 60 between the HEX 50 and the HEX 52 in a direction along the Z-axis. According to the present example, the pressure plates 56 and 58 are disposed on and overlap opposite sides of the MPP 76 along the Y axis. The pressure plates 56 and 58 are each separately fastened to the HEX 52 via fixing screws 80 that thread into threaded holes 82 formed in the HEX 52.

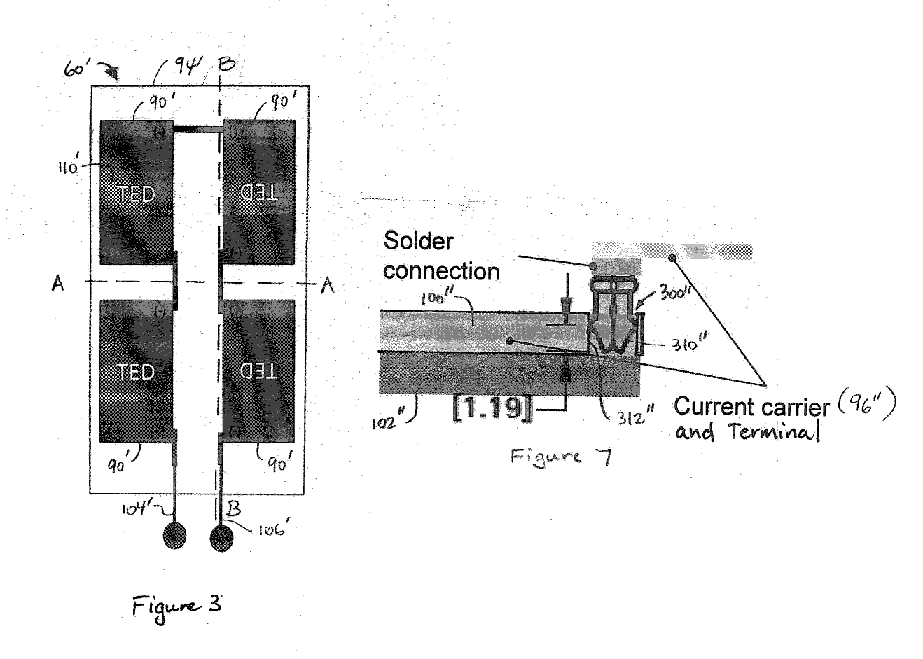

The TE assembly 60 includes complementary arrays of thermoelectric devices (TEDs) 90, heat transfer layers or thermal foil 92, an insulator 94, and current carriers 96. In various embodiments according the present teachings, the arrangement of the TEDs 90 and the thermal foil 92 can vary. In one example illustrated in FIG. 2, the TEDs 90 are arranged in a first two-by-four array. The thermal foil 92 is arranged in a complementary second two-by-four array disposed on the waste side of the TE assembly, and a complementary third two-by-four array disposed on the main side of the TE assembly. In another example illustrated in FIG. 3 and described in further detail below, the TEDs 90 and the thermal foil 92 are similarly arranged in two-by-two arrays. The thermal foil 92 is a thermally conductive part composed of a thermally conductive material and may be a thermal grease.

The insulator 94 is a thermally and electrically insulating part. The insulator 94 is configured to receive and retain the TEDs 90. The insulator 94 is further configured to receive and retain the current carriers 96 so that during assembly of the TE assembly 60 the insulator 94 and the current carriers 96 can be assembled to the remaining components together, and the current carriers 96 can form electrical connections between the TEDs 90. In this manner, the insulator 94 serves as a jig for maintaining the current carriers 96 and the TEDs 90 in a desired positional relationship relative to the insulator 94 and each other during assembly and in the finally assembled TE assembly 60.

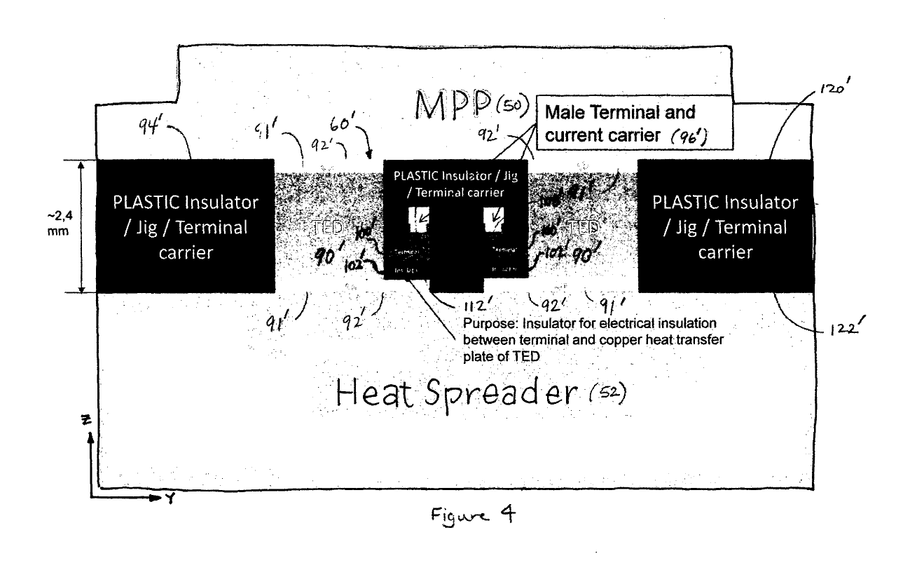

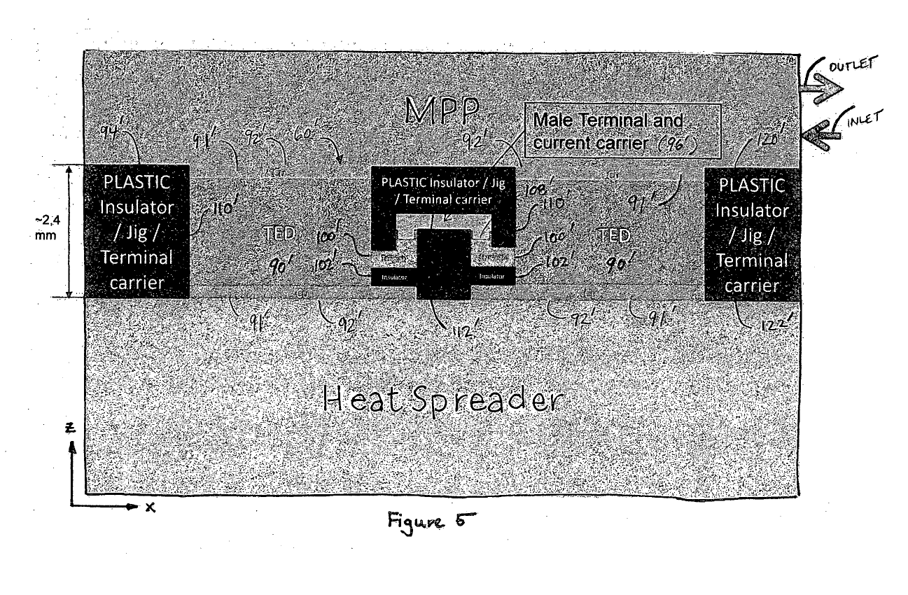

FIG. 3 is a block diagram schematically illustrating another TE assembly 60′ according to the present teachings. FIG. 4 is a sectional view along line A-A of FIG. 3 schematically illustrating the TE assembly 60′ in further detail. FIG. 5 is a sectional view along line B-B of FIG. 3 schematically illustrating the TE assembly 60′ in further detail. The TE assembly 60 and the TE assembly 60′ The TE assembly 60′ are substantially similar except in the number and arrangement of TEDs and thermal foil as noted above. In the drawings and the following description of the TE assembly 60′ similar reference numbers will be reused (e.g. 60, 60′) to indicate correspondence between reference elements with the understanding that the description of the TE assembly 60′ applies equally to the TE assembly 60 unless otherwise noted.

The TE assembly 60′ includes complementary arrays of thermoelectric devices (TEDs) 90′ including heat transfer layers or conductive plates 91′, thermal grease 92′, an insulator 94′, and current carriers 96′ arranged in relation to each other. The TEDs 90′ each include one or more thermoelectric elements and leads comprising terminals 100′ and optionally electrical insulators 102′ for isolating respective terminals 100′ and adjacent electrically conductive structures. Two of the terminals 100′ can connect to positive and negative lead wires 104′ and 106′ which connect the TE assembly 60′ to the power supply and control system 30. The conductive plates 91′ are composed of a thermally conductive material. The terminals 100′ include receptacles 108′ which engage or contact respective current carriers 96′.

The insulator 94′ is a thermally and electrically insulating part, and may be composed of any material with a suitably low thermal conductivity and a suitably low electrical conductivity. The insulator 94′ may be a monolithic part (i.e. single piece part), or comprise two or more parts. In the present example, the insulator 94′ is a monolithic part composed of a plastic or polymeric material. In various embodiments, the polymeric material can be polypropylene (PP), polyamide 6-6 (PA66), Acrylonitrile butadiene styrene (ABS). The insulator 94′ includes openings 110′, and receptacles 112′. The openings 110′ each receive and retain a corresponding one of the TEDs 90′ in its desired position within the TED array. As best seen in FIGS. 4 and 5, the openings 110′ extend through the insulator 94 between a first side 120′ facing the HEX 50 and a second side 122′ facing the HEX 52 in a lateral direction along axis Z. The receptacles 112′ each receive and retain respective current carriers 96′ and are located at intermediate lateral positions between the first and second sides 120′ and 122′. The insulator 94′ can be configured to absorb all or part of the compressive load applied by the pressure plates 56, 58. For example, a thickness of the insulator 94′ in the lateral direction may be equal to, less than, or greater than a thickness of the TEDs 90′ so that compressive forces are divided between the insulator 94′ and the TEDs 90′.

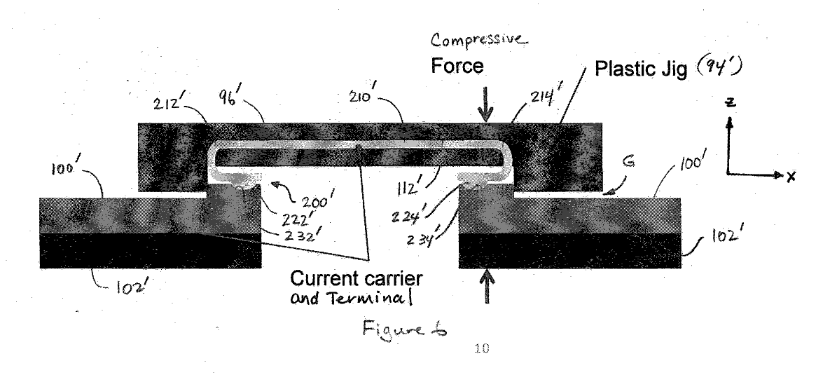

FIG. 6 is a sectional view along line B-B of FIG. 3 schematically illustrating the current carriers 96′ in further detail. FIG. 6 further illustrates an exemplary electrical connection 200′ made through intimate contact and compressive forces between the current carriers 96′ and the terminals 100′. The compressive forces are illustrated by the arrows in FIG. 6. The current carriers 96′ are composed of an electrically conductive material. In various embodiments, the material can include aluminum, copper or bronze which may be tinned or untinned. In various embodiments, the current carriers 96′ are substantially identical, however the present teachings apply to current carriers that differ in some respects, for example in length. The current carriers 96′ each include a bridge 210′ connecting ends 212′, 214′. The bridge 210′ engages and is releasably secured within a corresponding one of the receptacles 112′. In various embodiments, the bridge 210′ engages the receptacles 112′ in a frictional and/or snap fit.

The ends 212′, 214′ are c-shaped and form a linear flex-spring of a cantilever type. The flex-spring creates an electrical contact between the bridge 210′ and the current carriers 96′. During operation of the TE assembly 60′, the flex-spring maintains this contact by storing and releasing mechanical energy as a pressure or force on the TE assembly 60′ in the Z direction varies due to thermal expansion and contraction of the TE assembly 60′. The ends 212′, 214′ include convex protrusions 222′, 224′, respectively. The convex protrusions 222′, 224′ engage and intimately contact complementary concavities 232′, 234′, respectively, formed in the terminals 100′. In various embodiments, a gap G may be present between the insulator 94′ and the terminal 100′ in an assembled state. Alternately the gap G may not be present in the assembled state and the terminal 100′ may serve as a stop.

FIG. 7 is a sectional view illustrating other carriers 96″ providing an alternate connection 300″ for a thermoelectric assembly according to the present disclosure. The connection 300″ is made through engagement in a frictional fit between male and female parts. The carriers 96″ are substantially similar to the carriers 96′, except as now described. Male parts 310″ replace protrusions 222′, 224′ and are soldered to ends 222″, 224″. The male parts 310″ are tubular terminals with a tapered, contoured outer surface which facilitates engagement. Female parts 312″ are formed in terminals 100″ having a generally cylindrical shape.

An exemplary method 400 of manufacturing or assembling a TE assembly includes the following steps:

1. Providing an insulating part including a) openings extending through the insulating part from a first side to a second side and b) receptacles located between the first and second sides (step 402).

2. Engaging current carriers within the receptacles (step 404).

3. —Receiving thermoelectric devices within the openings, the thermoelectric devices having terminals (step 406).

4. Electrically connecting the thermoelectric devices via the current carriers (408).

In various embodiments, the step 408 of electrically connecting the thermoelectric devices is performed during the step 406 of receiving the thermoelectric devices within the openings. Further, the step 408 of electrically connecting can include a) pressing the current carriers against the terminals (step 410) and/or b) one of the terminals and the current carriers receiving an opposite one of the terminals and the current carriers in a press fit (step 412).

Those skilled in the art will appreciate thermal management systems according to the present teachings can include one or more of the following features and advantages:

1. During manufacturing, a monolithic plastic part can act as a jig holding multiple TEDs in place and ensure accurate build reproducibility.

2. In a finished thermoelectric assembly, the plastic part can provide thermal insulation between main side and waste side heat exchangers coupled to thermoelectric devices, such as for example a heat spreader and an MPP as illustrated and described with reference to FIGS. 1-5.

3. Conductive terminals used to connect TEDs, for example copper terminals, employing a friction, snap and/or compression fit can improve manufacturing efficiency and reproducibility of a thermoelectric assembly.

4. A current carrier having conductive terminals can be used in place of conventional wires or cables used to connect TEDs.

5. Designs for thermoelectric assemblies employing TEDs connected by conductive terminals without cables can be lower in cost and complexity, and higher in manufacturing ease and reproducibility than conventional thermoelectric assembly designs.

Discussion of the various embodiments herein has generally followed the embodiments schematically illustrated in the figures. However, it is contemplated that the particular features, structures, or characteristics of any embodiments discussed herein may be combined in any suitable manner in one or more separate embodiments not expressly illustrated or described. In many cases, structures that are described or illustrated as unitary or contiguous can be separated while still performing the function(s) of the unitary structure. In many instances, structures that are described or illustrated as separate can be joined or combined while still performing the function(s) of the separated structures.

Various embodiments have been described above. Although the present teachings have been described with reference to these specific embodiments, the descriptions are intended to be illustrative and are not intended to be limiting. Various modifications and applications may occur to those skilled in the art without departing from the spirit and scope of the teachings described herein.

1. A thermoelectric assembly, comprising:
an insulator having openings extending through the insulator from a first side to a second side, and receptacles located between the first and second sides;
a current carrier releasably secured to the insulator, and having ends; and
thermoelectric assemblies received within the openings, and having terminals connected to the ends.

2. A method of assembling a thermoelectric assembly, comprising:
providing an insulating part including:
a) openings extending through the insulating part from a first side to a second side and
b) receptacles located between the first and second sides;
engaging current carriers within the receptacles;
receiving thermoelectric devices within the openings, the thermoelectric devices having terminals; and
electrically connecting the thermoelectric devices via the current carriers.
